(19) United States
(12) Patent Application Publication
(10) Pub. No.: US 2014/0349491 A1
(43) Pub. Date: Nov. 27, 2014

(54) METHODS AND APPARATUS FOR SELECTIVE OXIDATION OF A SUBSTRATE

(71) Applicant: APPLIED MATERIALS, INC., Santa Clara, CA (US)

(72) Inventors: AGUS SOFIAN TJANDRA, San Jose, CA (US); ROGER BENSON TSAI, Cupertino, CA (US); MATTHEW SCOTT ROGERS, Mountain View, CA (US)

(73) Assignee: APPLIED MATERIALS, INC., Santa Clara, CA (US)

(21) Appl. No.: 14/281,020

(22) Filed: May 19, 2014

Related U.S. Application Data
(60) Provisional application No. 61/827,171, filed on May 24, 2013.

(51) Int. Cl. H01L 21/02; H01L 29/04

(52) U.S. Cl. CPC H01L 21/02236; H01L 21/02164; H01L 29/04
USPC 438/773

(57) ABSTRACT

Methods for improving selective oxidation of polysilicon against silicon nitride in a process chamber are provided herein. In some embodiments, a method of selectively oxidizing a substrate disposed within a process chamber includes exposing a substrate having an exposed polysilicon layer and an exposed silicon nitride layer to a hydrogen-containing gas; heating the substrate to a process temperature of at least about 850 degrees Celsius; adding an oxygen containing gas to the process chamber while maintaining the substrate at the process temperature to create a mixture of the hydrogen-containing gas and the oxygen-containing gas; and exposing the substrate to the mixture while at the process temperature to selectively form an oxide layer atop the polysilicon layer substantially without forming an oxide layer atop the silicon nitride layer.

### CROSS-REFERENCE TO RELATED APPLICATIONS

This application claims benefit of U.S. provisional patent application Ser. No. 61/827,171, filed May 24, 2013, which is herein incorporated by reference.

### FIELD

Embodiments of the present disclosure generally relate to substrate processing.

### BACKGROUND

In the manufacture of semiconductor devices, selective oxidation is used to target certain materials, such as silicon and oxides of silicon, while avoiding oxidation of other materials such as metals or silicon nitride. However, the inventors have observed that no satisfactory oxidation processes have been developed that can be used to oxidize polysilicon with good selectivity against silicon nitride (i.e., little or no oxidation of silicon nitride).

Accordingly, the inventors have provided improved methods for selective oxidation of polysilicon against silicon nitride.

### SUMMARY

Methods for improving selective oxidation of polysilicon against silicon nitride in a process chamber are provided herein. In some embodiments, a method of selectively oxidizing a substrate disposed within a process chamber includes exposing a substrate having an exposed polysilicon layer and an exposed silicon nitride layer to a hydrogen-containing gas; heating the substrate to a process temperature of at least about 850 degrees Celsius; adding an oxygen containing gas to the process chamber while maintaining the substrate at the process temperature to create a mixture of the hydrogen-containing gas and the oxygen-containing gas; and exposing the substrate to the mixture while at the process temperature to selectively form an oxide layer atop the polysilicon layer substantially without forming an oxide layer atop the silicon nitride layer.

In some embodiments, a method of selectively oxidizing a substrate disposed within a process chamber includes: exposing a substrate having an exposed polysilicon layer and an exposed silicon nitride layer to a non-reactive gas; heating the substrate to a process temperature of at least about 850 degrees Celsius after exposing the substrate to the non-reactive gas; evacuating the non-reactive gas from the process chamber after heating the substrate; subsequently exposing the substrate to a hydrogen-containing gas while maintaining the substrate at the process temperature of at least about 850 degrees Celsius; adding an oxygen-containing gas to the process chamber while maintaining the substrate at the process temperature to create a mixture of the hydrogen-containing gas and the oxygen-containing gas, wherein the mixture of the hydrogen-containing gas and the oxygen-containing gas comprises at least 80 volumetric percent hydrogen-containing gas; and exposing the substrate to the mixture while at the process temperature to selectively form an oxide layer atop the polysilicon layer substantially without forming an oxide layer atop the silicon nitride layer.

In some embodiments, a computer readable medium is provided having instructions stored thereon that, when executed, causes a process chamber to perform a method of selectively oxidizing a substrate within a process chamber. The method may include any of the methods disclosed herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a flow chart of a method for oxidizing a substrate in a process chamber in accordance with some embodiments of the present disclosure.

FIGS. 2A-B respectively depict a semiconductor structure during stages of fabrication in accordance with some embodiments of the present disclosure.

FIG. 3 depicts a schematic sectional side view of a process chamber suitable for use in accordance with some embodiments of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for improving selective oxidation in a process chamber are provided herein. The methods and apparatus described herein may advantageously provide for the selective oxidation of polysilicon against silicon nitride. Although not limiting in scope, the present disclosure may be particularly advantageous for the fabrication of memory devices, such as flash memory devices, for example 3-dimensional (3D) NAND flash memory devices, specifically with respect to scaled down NAND flash memory devices, or other suitable device, having, for example, a 45 nm, 30 nm, or 20 nm node size.

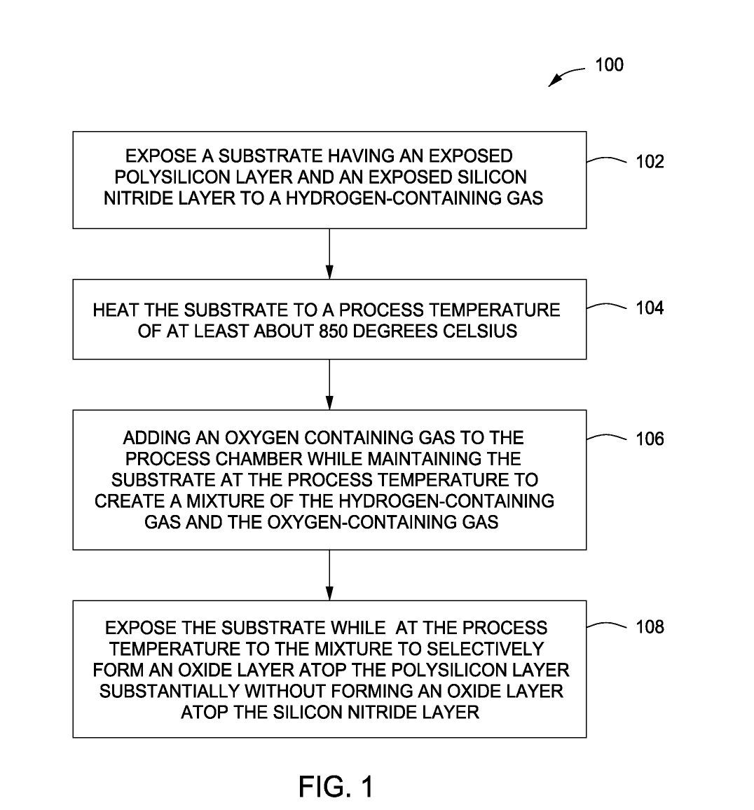

FIG. 1 depicts a flowchart of a method 100 of selectively oxidizing a substrate disposed in a process chamber. Selective oxidation requirements may arise when oxidation of a first material needs to be carried out in the presence of second, different material, such as, for example, the oxidation of polysilicon in the presence of silicon nitride. In such cases, the oxidation process needs to be carried out without abnormal oxidation of the exposed silicon nitride layer. As used herein, selective oxidation refers to the oxidation of some portions of a structure or device on a substrate (e.g., materials desired to be oxidized) with little or no oxidation on other exposed portions of the structure, device, and/or substrate (e.g., materials where oxidation is not desired).

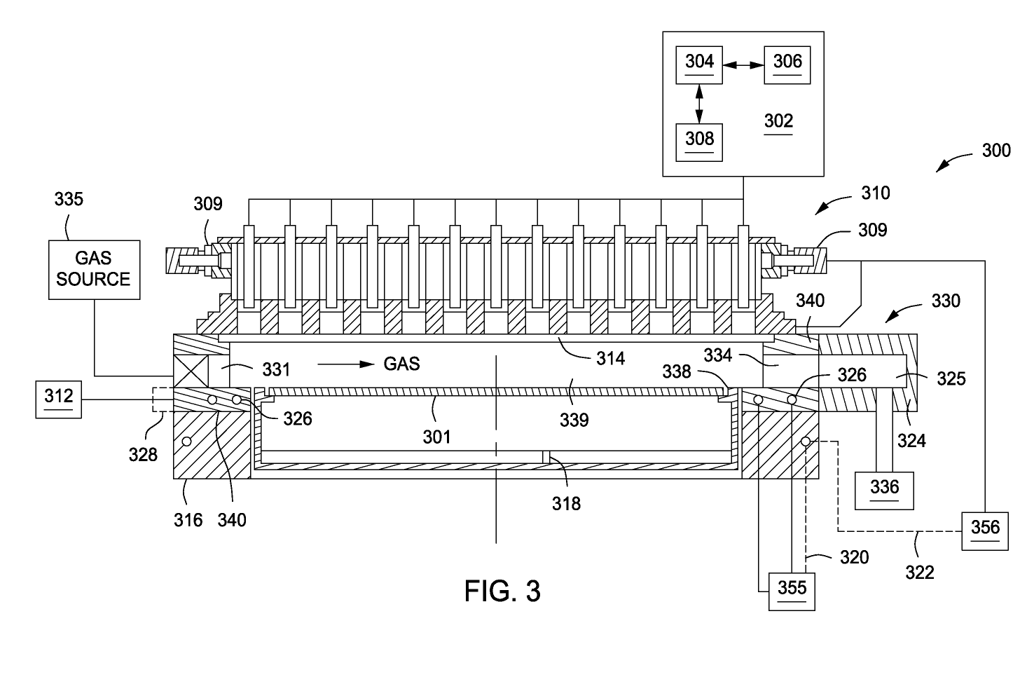

The process chamber may be any type of process chamber configured to perform a selective oxidation process as provided herein. Examples of suitable process chambers include any of the RADIANCE®, RADIANCE® PLUS, or VANTAGE® process chambers, or any other process chamber capable of performing a thermal process, for example a rapid thermal process (RTP), all available from Applied Materials, Inc., of Santa Clara, Calif. Other suitable process chambers, including those available from other manufacturers may also be used in accordance with the teachings provided herein. In some embodiments, the process chamber may be similar to the process chamber described below with respect to FIG. 3.

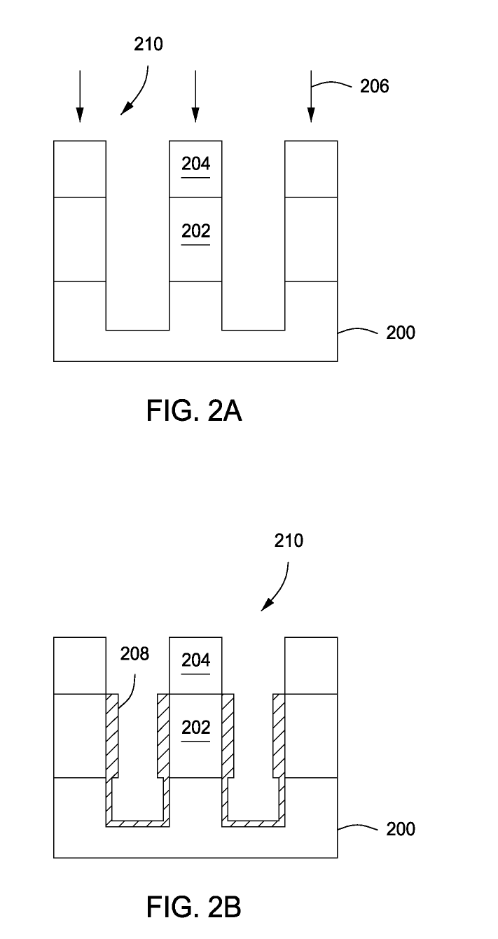

The method 100 is described herein with respect to the illustrative semiconductor structure depicted in FIGS. 2A-B. The method 100 generally begins at 102, by exposing a substrate 200 within a process chamber to a suitable hydrogen-containing gas, as described below. The substrate 200 may comprise any material suitable for fabrication of the type of memory device (e.g., a 3D NAND flash memory device) identified above, for example, such as crystalline silicon (e.g., Si<100> or Si<111>), strained silicon, silicon germanium, doped or undoped polysilicon, doped or undoped silicon wafers, patterned or non-patterned wafers, silicon on insulator (SOI), carbon doped silicon oxides, doped silicon, or the like.

As depicted in FIG. 2A, the substrate 200 comprises an exposed polysilicon layer 202 and an exposed silicon nitride layer 204, for example, due to features 210 such as trenches, vias, dual damascene structures, or the like. The substrate 200 is also partially exposed, for example, due to the features 210 formed in or on the substrate 200. The features 210 may be formed through any suitable process, for example, such as an etch process. Although the features 210 may generally have any suitable dimensions, in some embodiments, the features 210 may be high aspect ratio features, i.e., a feature having a side wall to width, or bottom, ratio of greater than about 4:1. In some embodiments, the suitable hydrogen-containing gas can be, for example, a gas that provides hydrogen and, optionally, other essentially non-reactive elements, such as nitrogen or the like. In some embodiments, the hydrogen-containing gas can be one or more of hydrogen gas (H₂), ammonia (NH₃), or the like.

In some embodiments, the substrate is exposed to a non-reactive gas prior to exposure to the hydrogen-containing gas. In some embodiments, the non-reactive gas is used to purge the process chamber to prevent any unwanted chemical reactions. For example, in some embodiments, the purge is accomplished by pumping all gases out of the process chamber and then flowing a non-reactive gas into the process chamber to create a non-reactive gas atmosphere in the process chamber. The non-reactive gas can be, for example, a gas that does not react with any exposed substrate materials during processing. In some embodiments, the non-reactive gas may include, for example, helium (He), nitrogen gas (N₂), argon (Ar), neon (Ne), xenon (Xe), or the like.

Next, at 104, the substrate 200 is heated to a process temperature of greater than about 850 degrees Celsius. The inventors have observed that oxidation reaction is driven by the temperature and pressure in the reaction zone. The reaction zone is heated by convection from the hot substrate and by energy released from the oxidation reaction. Temperatures required to drive the reaction are thus found in the immediate vicinity of the substrate surface. In some embodiments, the reaction may be confined to a zone up to 1 cm from the substrate surface. The inventors have observed that temperatures above 850 degrees Celsius are generally effective to promote selective oxidation reactions. In some embodiments, the substrate is heated to a process temperature of about 850 degrees Celsius to about 950 degrees Celsius. The substrate 200 may be heated to the process temperature either before or after exposing the substrate 200 to the hydrogen-containing gas. In some embodiments, the substrate is heated to the processing temperature after purging the process chamber with the non-reactive gas.

Additionally, the inventors have observed that, in general, as the pressure increases, the concentration of undesirable oxidizing species declines. Thus, higher chamber pressures result in fewer radical species because oxygen radicals are quickly scavenged by hydrogen containing species. In some embodiments, the processing pressure within the process chamber is about 300 Torr to about 600 Torr. In some embodiments, the processing pressure within the process chamber is about 530 Torr.

Next, at 106, a suitable oxygen-containing gas is added to the process chamber while maintaining the substrate at the process temperature to create a mixture 206 of hydrogen-containing gas and oxygen-containing gas. In some embodiments, the suitable oxygen containing gas can be for example, a gas that contains oxygen or oxygen and other essentially non-reactive elements, such as nitrogen, or the like. In some embodiments, the oxygen containing gas may be, for example, oxygen gas (O₂), ozone (O₃), nitrous oxide (N₂O), or the like. Next, at 108, the substrate 200 at the process temperature is exposed to the mixture 206 to selectively form an oxide layer atop the polysilicon layer substantially without forming an oxide layer atop the silicon nitride layer. The hydrogen-containing gas and the oxygen-containing gas react, generating in-situ steam, which in turn drives the selective oxidation reaction on the substrate.

The inventors have observed that if there is too much oxygen in the gas mixture 206, oxygen radical species will predominate, causing unwanted oxidation reactions. Due to their size, oxygen radical species are better able to diffuse into a silicon nitride structure than are water molecules. Thus, higher concentration of oxygen radical species results in lower selectivity for polysilicon. In some embodiments, the mixture 206 contains at least 80 volumetric percent hydrogen-containing gas with the balance being predominantly, or substantially only, the oxygen-containing gas. In some embodiments, the mixture 206 contains at least 90 volumetric percent hydrogen-containing gas with the balance being predominantly, or substantially only, the oxygen-containing gas. The gas mixture 206 may be flowed at any suitable flow rate depending upon, for example, one or more of the substrate/chamber size, the materials of the substrate, the gas mixture composition, or the like. In some embodiments, the gas mixture 206 may be provided at a total flow rate in the range of about 5,000 to about 40,000 sccm.

FIG. 2B depicts a substrate 200 after selective oxidation has been performed. Oxide layer 208 has grown adjacent to polysilicon layer 202 but not adjacent to silicon nitride layer 204. In some embodiments, at the process conditions described above, a oxidation reaction duration of about 2 to about 8 minutes is sufficient to produce a oxide layer about 50 to about 120 angstroms thick on polysilicon. In some embodiments, the ratio of oxide growth on the polysilicon layer to oxide growth on the silicon substrate is about 2:1 to about 5:1. After formation of the oxide layer 208, the temperature may be ramped down and the reaction chamber may be pumped out and non-reactive gas charged. The chamber may be purged briefly to ensure no potentially reactive gases remain to degrade the substrate, and then the substrate is removed from the chamber for further processing.

FIG. 3 depicts a schematic sectional side view of a thermal processing apparatus 300 for use in accordance with some embodiments of the present disclosure. The thermal processing apparatus 300 generally comprises a lamp assembly 310, a chamber assembly 330 defining a processing volume 339, and a substrate support 338 disposed in the processing volume 339.

The lamp assembly 310 is positioned above the chamber assembly 330 and is configured to supply heat to the processing volume 339 via a quartz window 314 disposed on the chamber assembly 330. The lamp assembly 310 is configured to house a process heating source, such as a plurality of tungsten-halogen lamps for providing a tailored infrared heating means to a substrate 301 disposed on the substrate support 338. One or more pyrometers (one pyrometer 318 shown) may be disposed beneath the substrate 301 and aimed at a backside of the substrate 301 to provide data corresponding to the temperature of the substrate. The data from the one or more pyrometers may be provided to a controller (e.g., 302) to facilitate feedback control over the process heating source and for use in facilitating the methods described herein.

The chamber assembly 330 generally comprises a base ring 340 having one or more chamber walls defining the processing volume 339 with the quartz window 314 and a bottom wall 316. Although the term ring is used herein, the base ring 340 need not be circular and other shapes are contemplated as well. The base ring 340 may have an inlet 331 coupled to a gas source 335 to provide one or more process gases to the processing volume 339 (such as the hydrogen containing gas, oxygen containing gas, and/or the non-reactive gas discussed above). An outlet 334, disposed on an opposite side of the base ring 340 from the inlet 331, is coupled to an exhaust assembly 324 which is in fluid communication with a pump system 336. The exhaust assembly 324 defines an exhaust volume 325, which is in fluid communication with the processing volume 339 via the outlet 334. The exhaust volume 325 is designed to allow uniform gas flow distribution across the processing volume 339.

In some embodiments, a heating apparatus may be provided at least partially disposed within or coupled to the chamber walls. For example, in some embodiments, a first heat exchanger 355 is coupled to the base ring 340 to control the temperature of the chamber walls by circulating a heat exchange fluid through one or more conduits 326 disposed in the base ring 340. In some embodiments, the first heat exchanger 355 is set to at least 60 degrees Celsius. Alternatively or in combination, a heat jacket 328 may be thermally coupled to the base ring 340 to provide heat to the chamber walls, for example, by flowing a heat transfer fluid through the heat jacket 328, by providing heater elements, such as resistive heaters or heat lamps, within the heat jacket 328, or the like.

In some embodiments, a second heat exchanger 356 is coupled to the lamp assembly 310 to allow heat exchange fluid to be circulated to the lamp assembly 310 through an inlet 309 to keep the lamp assembly 310 cool during processing. In some embodiments, the first heat exchanger and the second heat exchanger may be maintained at different temperatures. In some embodiments, the second heat exchanger 356 may also be coupled to the bottom wall 316, as indicated by dashed line 322. Alternatively, in some embodiments, the first heat exchanger 355 may also be coupled to the bottom wall 316, as indicated by dashed line 320.

A thermocouple 312, or other suitable sensor, may be coupled to the base ring 340 to monitor the outer chamber wall temperature and to determine the inner chamber wall temperature. The thermocouple 312 may be part of, or coupled to, a system controller, such as the system controller 302 that may control the operations of the thermal processing apparatus 300.

To facilitate control of the thermal processing apparatus 300 as described above, a controller 302 comprises a central processing unit (CPU) 304, a memory 306, and support circuits 308 for the CPU 304 and facilitates control of the components of the thermal processing apparatus 300. The controller 302 may be one of any form of general-purpose computer processor that can be used in an industrial setting for controlling various chambers and sub-processors. The memory 306, or computer-readable medium, of the CPU 304 may be one or more of readily available memory such as random access memory (RAM), read only memory (ROM), floppy disk, hard disk, or any other form of digital storage, local or remote. The support circuits 308 are coupled to the CPU 304 for supporting the processor in a conventional manner. These circuits include cache, power supplies, clock circuits, input/output circuitry and subsystems, and the like. The methods performed in the thermal processing apparatus 300, or at least portions thereof, may be stored in the memory 306 as a software routine. The software routine may also be stored and/or executed by a second CPU (not shown) that is remotely located from the hardware being controlled by the CPU 304.

Thus, methods and apparatus for improving selectivity against metals have been provided herein. The inventive methods and apparatus may advantageously provide improve selective oxidation against metals and minimize the transport of contaminants to the substrate via condensation formed in the process chamber.

While the foregoing is directed to embodiments of the present disclosure, other and further embodiments of the disclosure may be devised without departing from the basic scope thereof.

1. A method of selectively oxidizing a substrate disposed within a process chamber, comprising:
exposing a substrate having an exposed polysilicon layer and an exposed silicon nitride layer to a hydrogen-containing gas;
heating the substrate to a process temperature of at least about 850 degrees Celsius;
adding an oxygen-containing gas to the process chamber while maintaining the substrate at the process temperature to create a mixture of the hydrogen-containing gas and the oxygen-containing gas; and
exposing the substrate to the mixture while at the process temperature to selectively form an oxide layer atop the polysilicon layer substantially without forming an oxide layer atop the silicon nitride layer.

2. The method of claim 1, further comprising exposing the substrate to a non-reactive gas prior to exposing the substrate to a hydrogen-containing gas.

3. The method of claim 2, wherein the non-reactive gas is one of helium (He), nitrogen gas (N₂), argon (Ar), neon (Ne), or xenon (Xe).

4. The method of claim 2, further comprising heating the substrate to the process temperature after exposing the substrate to the non-reactive gas.

5. The method of claim 4, further comprising evacuating the non-reactive gas from the process chamber prior to exposing the substrate to the hydrogen-containing gas.

6. The method of claim 1, wherein the hydrogen-containing gas is hydrogen gas (H₂) or ammonia (NH₃).

7. The method of claim 1, wherein the oxygen-containing gas is oxygen gas (O₂), ozone (O₃), or nitrous oxide (N₂O).

8. The method of claim 1, wherein the mixture of the hydrogen-containing gas and the oxygen-containing gas comprises at least 80 volumetric percent hydrogen-containing gas.

9. The method of claim 1, wherein the mixture of the hydrogen-containing gas and the oxygen-containing gas comprises at least 90 volumetric percent hydrogen-containing gas.

10. The method of claim 1, wherein a pressure within the process chamber is about 300 Torr to about 600 Torr.

11. The method of claim 1, wherein a pressure within the process chamber is about 530 Torr.

12. The method of claim 1, wherein the substrate is silicon.

13. The method of claim 12, wherein a ratio of oxide growth on the polysilicon layer to oxide growth on the silicon substrate is about 2:1 to about 3:1.

14. A computer readable medium, having instructions stored thereon that, when executed, causes a process chamber to perform a method of selectively oxidizing a substrate within a process chamber, the method comprising:
exposing a substrate comprising an exposed polysilicon layer and an exposed silicon nitride layer to a hydrogen-containing gas;
heating the substrate to a process temperature of at least about 850 degrees Celsius;
adding an oxygen-containing gas to the process chamber while maintaining the substrate at the process temperature to create a mixture of the hydrogen-containing gas and the oxygen-containing gas; and
exposing the substrate to the mixture while at the process temperature to selectively form an oxide layer atop the polysilicon layer substantially without forming an oxide layer atop the silicon nitride layer.

15. The computer readable medium of claim 14, further comprising exposing the substrate to a non-reactive gas prior to exposing the substrate to a hydrogen-containing gas.

16. The computer readable medium of claim 15, further comprising heating the substrate to the process temperature after exposing the substrate to the non-reactive gas.

17. The computer readable medium of claim 15, further comprising evacuating the non-reactive gas from the process chamber prior to exposing the substrate to the hydrogen-containing gas.

18. The computer readable medium of claim 14, wherein the mixture of the hydrogen-containing gas and the oxygen-containing gas comprises at least 80% hydrogen-containing gas.

19. The computer readable medium of claim 14, wherein a ratio of oxide growth on the polysilicon layer to oxide growth on the substrate is about 2:1 to about 3:1.

20. A method of selectively oxidizing a substrate disposed within a process chamber, comprising:
exposing a substrate having an exposed polysilicon layer and an exposed silicon nitride layer to a non-reactive gas;
heating the substrate to a process temperature of at least about 850 degrees Celsius after exposing the substrate to the non-reactive gas;
evacuating the non-reactive gas from the process chamber after heating the substrate;
subsequently exposing the substrate to a hydrogen-containing gas while maintaining the substrate at the process temperature of at least about 850 degrees Celsius;
adding an oxygen-containing gas to the process chamber while maintaining the substrate at the process temperature to create a mixture of the hydrogen-containing gas and the oxygen-containing gas, wherein the mixture of the hydrogen-containing gas and the oxygen-containing gas comprises at least 80 volumetric percent hydrogen-containing gas; and
exposing the substrate to the mixture while at the process temperature to selectively form an oxide layer atop the polysilicon layer substantially without forming an oxide layer atop the silicon nitride layer.
